(19) United States
(12) Patent Application Publication
(10) Pub. No.: US 2016/0265498 A1
(43) Pub. Date: Sep. 15, 2016

(54) CIRCUIT FOR DETECTING FAULT IN FUEL INJECTION SYSTEM

(71) Applicant: Caterpillar Inc., Peoria, IL (US)

(72) Inventors: Daniel Puckett, Peoria, IL (US); William Eugene Hoban, JR., Dunlap, IL (US)

(73) Assignee: Caterpillar Inc., Peoria, IL (US)

(21) Appl. No.: 15/157,662

(22) Filed: May 18, 2016

(51) Int. Cl. F02M 51/06; G01R 31/02; G01R 31/00

(52) U.S. Cl. CPC F02M 51/0603; G01R 31/007; G01R 31/025

(57) ABSTRACT

A driver circuit for a fuel injector is provided. The fuel injector is connected to an Engine Control Module (ECM) having a high-side terminal and a low-side terminal. The driver circuit includes a fault detection system for detecting a short-to-ground fault. The fault detection system includes a first module to measure a forward current flowing through the high-side terminal of the ECM and a second module to measure a return current flowing through the low-side terminal of the ECM. Further, the fault detection system includes a third module to compute a differential current based on the forward current and the return current. The fault detection system includes a fourth module to compare the differential current with a threshold current, and trigger a fault and interrupt the flow of the forward current when the differential current is greater than the threshold current.

### TECHNICAL FIELD

The present disclosure relates to fuel injection systems. More particularly, the present disclosure relates to a circuit for detecting fault in a fuel injection system.

### BACKGROUND

Typically, engines use fuel injectors to supply fuel to one or more cylinders of the engine. The fuel injectors are controlled by an Engine Control Module (ECM) to supply predetermined quantity of fuel to the cylinders in synchronization with the movement of the pistons. The timing of fuel injection and quantity of the fuel injected are critical parameters that may affect the overall performance of the engine.

During operation of the engine, a short-to-ground fault may occur due to short-circuiting of one or more fuel injector circuits to ground. Typically, ECM has a high-side terminal connected to a power source and a low-side terminal. Commonly, the short-to-ground fault may occur in a wire connecting the low-side terminal of the ECM and the fuel injector. The short-to-ground fault may cause an overcurrent to flow through the fuel injector. This may result in a late end of injection (EOI) further leading to over-fueling of the engine. Additionally, in fuel injection systems in which multiple fuel injectors are electrically connected, the short-circuiting of one of the fuel injectors may lead to unintended actuation of the other connected fuel injectors. In some cases, it may result in catastrophic failures such as unwanted off-cycle fueling or extended fueling of the other fuel injectors.

U.S. Published Application No. 2015/0176517 describes an injector driver and a method of controlling the injector driver. A defect of a driving channel is detected by enabling an identification of safety inspection for each channel in a driving semiconductor during an idle mode. The injector driver includes a plurality of driving switches that operate an injector and a driving semiconductor that drives of the driving switches. In addition, the driving semiconductor determines a short defect of the injector during an idle mode and detects and stores the defective short in a channel unit.

### SUMMARY OF THE DISCLOSURE

In an aspect of the present disclosure, a driver circuit for a fuel injector is provided. The fuel injector is connected to an Engine Control Module (ECM). The driver circuit includes a power source, a first switch, a second switch, and a fault detection system. The first switch, located on a low-side terminal of the ECM, is configured to connect and disconnect the fuel injector to and from the power source. The second switch, located on a high-side terminal of the ECM, is configured to connect and disconnect the fuel injector to and from the power source. The driver circuit further includes a fault detection system for detecting a short-to-ground fault. The fault detection system includes a first module to measure a forward current flowing through the high-side terminal of the ECM. The fault detection system includes a second module to measure a return current flowing through the low-side terminal of the ECM. Further, the fault detection system includes a third module configured to compute a differential current based on the forward current and the return current. The fault detection system includes a fourth module configured to compare the differential current with a threshold current, and trigger a fault when the differential current is greater than the threshold current.

Other features and aspects of this disclosure will be apparent from the following description and the accompanying drawings.

### BRIEF DESCRIPTION OF THE DRAWINGS

FIG. 1 is a block diagram that illustrates an exemplary fuel injection system of an engine, in accordance with the concepts of the present disclosure;

FIG. 2 illustrates a driver circuit to detect a short-to-ground fault in the fuel injection system of FIG. 1, in accordance with the concepts of the present disclosure; and

FIG. 3 is a flow chart that illustrates a method for detecting the short-to-ground fault in the fuel injection system of FIG. 1, in accordance with the concepts of the present disclosure.

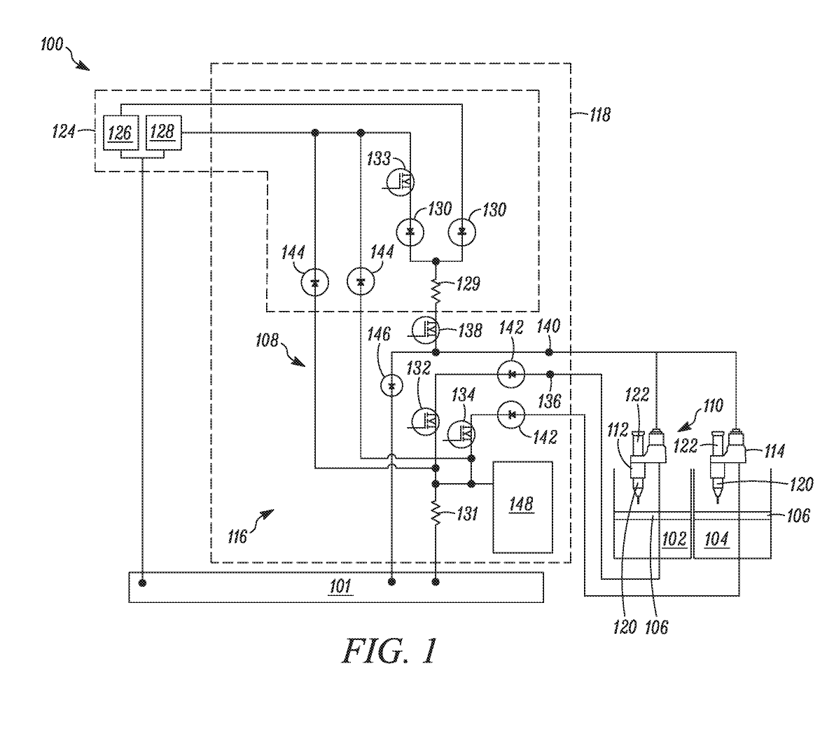

### DETAILED DESCRIPTION

Wherever possible, the same reference numbers will be used throughout the drawings to refer to the same or the like parts. Referring to FIG. 1, an engine system 100, such as an automotive vehicle engine or construction machinery engine is shown. More specifically, the engine system 100 is a compression ignition engine. The engine system 100 includes an engine block 101 having a number of cylinders (not shown) disposed in any one of an inline configuration, a V-configuration, a W-configuration, or an X-configuration, etc. For the purpose of illustration and simplicity, FIG. 1 shows only a first cylinder 102 and a second cylinder 104. However, the engine block 101 may include a plurality of cylinders without any limitation. Each of the first and the second cylinders 102, 104 include respective pistons 106 that reciprocates in the corresponding cylinders due to pressure energy generated by combustion of fuel inside the cylinders.

Further, as illustrated in FIG. 1, the engine system 100 includes a fuel injection system 108 which supplies the fuel into the first and second cylinders 102, 104. For example, the fuel injection system 108 may be employed in a diesel engine to inject diesel fuel. The fuel injection system 108 includes an injector bank 110 having a first fuel injector 112 and a second fuel injector 114, in association with the first cylinder 102 and the second cylinder 104, respectively. The fuel injectors 112, 114 are electrically actuable to inject the fuel into the cylinders 102, 104. In an embodiment, the fuel injection system 108 may include a number of injector banks, such as injector bank 110, associated with each cylinder set. Further, the injector bank 110 may include more than two fuel injectors, depending on the number of cylinders.

In an embodiment of the present disclosure, the fuel injection system 108 employs a driver circuit 116 for each of the injector banks 110. The driver circuit 116 is associated with the respective injector bank 110, to monitor and control an operation of the first and second fuel injectors 112, 114. The driver circuit 116 forms a part of an Engine Control Module (ECM) 118. The ECM 118 may, typically, include a microprocessor and a memory which are arranged to perform various routines to control the operation of the engine system 100. For example, the ECM 118 may be configured to monitor engine speed and load, and provide a feedback to the driver circuit 116 to control the timing of operation and the amount of fuel supplied to the fuel injectors 112, 114. Further, the driver circuit 116 receives signals indicating a location of the pistons 106 within the first and the second cylinders 102, 104, and accordingly actuates the fuel injectors 112, 114 to supply the fuel.

As shown in FIG. 1, each of the first and second fuel injectors 112,114, in the injector bank 110, includes an injection valve 120 and an actuator 122. The actuator 122 may be any one of a solenoid coil, a piezoelectric actuator, and the like. The actuator 122 is operable by the driver circuit 116 to cause the injector valve 120 to open and close, in order to control the injection of the fuel into the associated cylinders.

The driver circuit 116 also include a power source 124. In an embodiment, the power source 124 may be a combination of, for example, but not limited to, a battery 126, and a High Voltage Power Supply (HVPS) 128 working in conjunction, via a pair of diodes 130 and switch 133. The negative terminal of the power source 124 is further connected to ground via the engine block 101, as shown in FIG. 1. The driver circuit 116 may also include a boost circuit (not shown) which amplifies the power received from the battery 126. Such an arrangement may provide voltage proportional to the engine load by the first and second fuel injectors 112, 114. The driver circuit 116 may also include means for noise suppression, such as, a capacitor, or the like connected to the power source 124.

The driver circuit 116 includes a first selector switch 132 and a second selector switch 134, between one of the first fuel injector 112 and the second fuel injector 114, and the power source 124. More specifically, the first and second selector switches 132, 134 are connected to a low-side terminal 136 of the ECM 118, to controllably connect and disconnect the first and second fuel injectors 112, 114 to and from the power source 124. Further, the driver circuit 116 includes a multiplexed switch 138 connected to a high-side terminal 140 of the ECM 118 to controllably connect and disconnect the first and second fuel injectors 112, 114 to and from the power source 124.

In an embodiment of the present disclosure, the first and second selector switches 132, 134 are field effect transistors (FET's) with a drain connected to the first and second fuel injectors 112, 114, respectively. Similarly, the multiplexed switch 138 may also be a field effect transistor (FET) with a drain in connection with the first and second fuel injectors 112, 114. In particular, the power source 124, the multiplexed switch 138, and the first and second switches 132, 134 selectively form a closed loop electrical circuit with the first and second fuel injectors 112, 114. In another embodiment, the driver circuit 116 of the present disclosure may use an n-type MOSFET as switches 132, 134, 138. In various implementations, the injector banks 110 of the fuel injection system 108 share the low-side, that is, each of the injector banks 110 is connected to the same first and second selector switches 132, 134. Further, the first and second fuel injectors 112, 114 in each of the injector banks 110 may share the multiplexed switch 138 on the high-side between the power source 124 and the fuel injectors.

The driver circuit 116 includes diodes 142 connected between the low-side terminal 136 and the power source 124. The driver circuit 116 also include diodes 144 to ensure unidirectional current flow through the fuel injectors 112, 114. The driver circuit 116 also include additional diode 146 connected between the high-side terminal 140 and ground.

In an embodiment, the driver circuit 116 includes a controller 148 for operating the fuel injection system 108. Generally, the controller 148 may be a combination of, but not limited to, a processor, a Read Only Memory, a Random-Access Memory, a Logic Unit, a FPGA, etc. The controller 148 may primarily control the first and second selector switches 132, 134 and the multiplexed switch 138 in order to control the current flow through the driver circuit 116, and therefore the first and second fuel injectors 112, 114 for injection of the fuel. In an embodiment, the controller 148 may also be a part of the Engine Control Module (ECM) 118.

The controller 148 may be operable to selectively trigger the first and second fuel injectors 112, 114 at desired points in time, by closing the multiplexed switch 138 while operating the first and second selector switches 132, 134 in alternating on and off states, whereby a first average magnitude of current is supplied to the first fuel injector 112 during a first period of time and a second average magnitude of current is supplied to the second fuel injector 114 during a second period of time subsequent to the first period of time. Thus, the first and second fuel injectors 112, 114 are active or inactive based on signals from the controller 148. In an embodiment, the controller 148 may be communicably coupled to an operator interface (not shown). The operator interface may include one or more buttons, levers, displays, and the like, in order to receive various operator inputs and communicate output status of the driver circuit 116 with the operator.

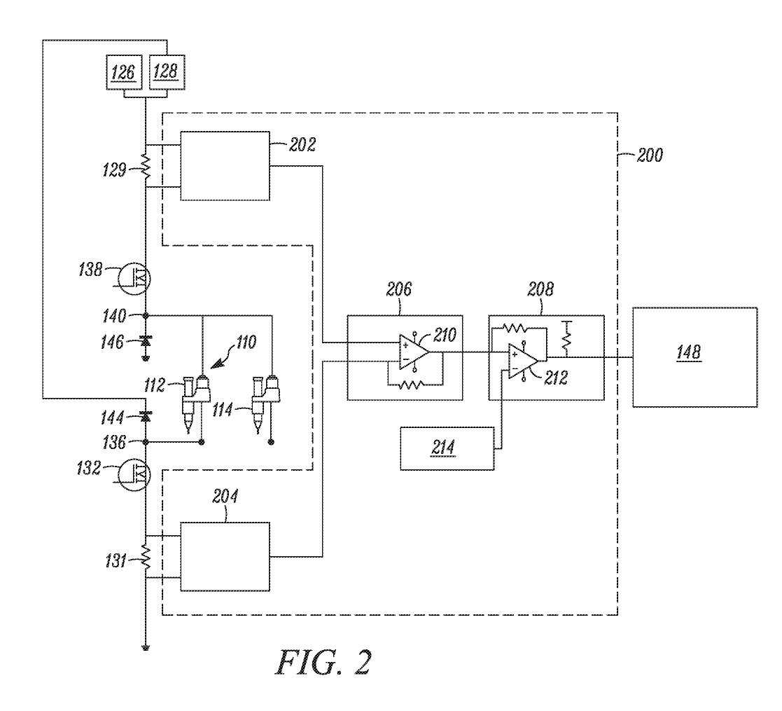

Referring to FIG. 2, a fault detection system 200 is provided to detect a short-to-ground fault in the fuel injection system 108. The fault may be due to short-circuit to ground or engine chassis of the engine block 101. In various embodiments, the short-to-ground fault may occur at the high-side i.e. in a wire connecting the high-side terminal 140 of the ECM 118 and the fuel injector 112. In other embodiments, the short-to-around fault may occur at the low-side i.e. in the return wire connecting the low-side terminal 136 of the ECM 118 and the fuel injector 112. As shown in FIG. 2, the fault detection system 200 may include a first module 202 connected to both sides of a resistor 129. The first module 202 is configured to measure a forward current flowing through the high-side terminal 140 of the ECM 118. In other words, the first module 202 measures the forward current flowing through the resistor 129. In various embodiments, the first module 202 may include commonly known circuit configurations to measure the forward current. In an embodiment, operational amplifier based circuits may be employed to measure the voltage across the resistor 129 which in turn may be used to compute the forward current.

As shown in FIG. 2, the fault detection system 200 includes a second module 204 connected to both sides of a resistor 131. The second module 204 is configured to measure a return current flowing through the low-side terminal 136 of the ECM 118. In other words, the second module 204 measures the return current flowing through the resistor 131. In various embodiments, the second module 204 may include commonly known circuit configurations to measure the return current. In an embodiment, operational amplifier based circuits may be employed to measure the voltage across the resistor 131, which in turn may be used to compute the return current.

The fault detection system 200 further includes a third module 206 to compute a differential current based on the forward current and the return current. More specifically, magnitude of the differential current represents the difference between magnitude of the forward current and magnitude of the return current. The third module 206 is operatively coupled with the first module 202 and the second module 204. As an example embodiment shown in FIG. 2, the third module 206 includes an operational amplifier (op-amp) 210. The op-amp 210 may include two input terminals and an output terminal. Output of the first module 202 is connected to one input terminal of the op-amp 210. Output of the second module 204 is connected to other input terminal of the op-amp 210. Specifically, the op-amp 210 receives the forward current from the first module 202 and the return current from the second module 204 and provides the differential current as output. In various embodiments, other commonly known circuit configurations may be used to compute the differential current.

Further, the fault detection system 200 includes a fourth module 208 to compare the differential current with a threshold input 214. The threshold input 214 is referred hereinafter as “threshold current”. As an example embodiment shown in FIG. 2, the fourth module 208 includes a comparator 212 to compare the differential current with the threshold current 214. The comparator 212 may include two input terminals and an output terminal. Output of the third module 206 is connected to one input terminal of the comparator 212. Other input terminal of the comparator 212 receives the threshold current 214. The threshold current 214 may be provided from various sources, for example, the ECM 118 of the engine system 100. In an embodiment, the controller 148 may be configured to activate or deactivate the threshold current 214. In one embodiment, the threshold current 214 may have a fixed predetermined value. In other embodiments, the controller 148 may also be configured to regulate a value of the threshold current 214. For example, the threshold current 214 may vary based on one or more environment parameters such as temperature, pressure, and humidity. The controller 148 controls the threshold current 214 based on user inputs received via the operator interface. Alternatively, the controller 148 may control the threshold current 214 based on predetermined instructions.

The fourth module 208 may be configured to trigger a fault if the differential current is greater than the threshold current 214. Upon detecting the fault, the fourth module 208 may send a signal to the controller 148 to open the multiplexed switch 138. This prevents over-fueling of the fuel injectors 110, 112 due to the fault. In various embodiments, a time duration for which the differential current is greater than the threshold current 214 is determined and compared against a predetermined time period to trigger the fault. This prevents triggering of the fault when the differential current is greater than the threshold current 214 for a brief time period.

In an example embodiment, the fourth module 208 may be further configured to measure a rise time of the differential current. The rise time of the differential current may help in identifying whether the short-to-ground fault has occurred at the high-side or the low-side. For example, a faster rise time may indicate that the short-to-ground fault has occurred at the high-side. This helps in improved troubleshooting and repair of the fuel injection system 108. Further, it may also help in making a decision whether to disable the fuel injectors 112, 114.

### INDUSTRIAL APPLICABILITY

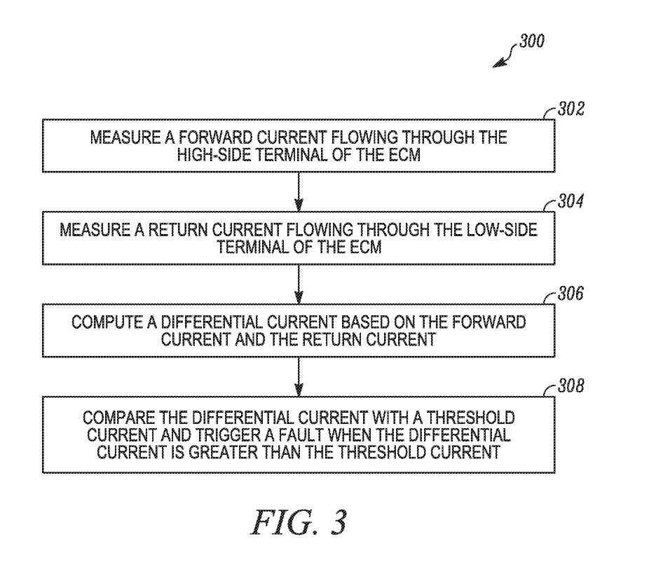

The present disclosure relates to the fault detection system 200 for detecting a short-to-ground fault in the fuel injector 112. Referring to FIG. 3, a method 300 of working of the fault detection system 200 is illustrated. The fault detection system includes the first module 202, the second module 204, the third module 206, and the fourth module 208. At step 302, the first module 202 measures the forward current flowing through the high-side terminal 140 of the ECM 118. At step 304, the second module 204 measures the return current flowing through the low-side terminal 136 of the ECM 118. In various embodiments, commonly known circuit configurations may be used by the first module 202 and the second module 204 to measure the forward current and the return current respectively.

At step 306, the third module 206 computes a differential current based on the forward current and the return current. The third module 206 is operatively coupled with the first module and the second module 204. The third module 206 receives the forward current from the first module 202 and the return current from the second module 204. As shown in FIG, 2, the fourth module 208 includes the op-amp 210 to compute the differential current. In various embodiments, other commonly known circuit configurations may be used by the fourth module 208 to compute the differential current.

At step 308, the fourth module 208 compares the differential current with the threshold current 214. As shown in FIG. 2, the fourth module 208 includes the comparator 212 to compare the differential current with the threshold current 214. In an embodiment, the controller 148 may also be configured to regulate a value of the threshold current 214. For example, the threshold current 214 may vary based on one or more environment parameters such as temperature, pressure, and humidity.

If the differential current is greater than the threshold current 214, the fourth module 208 is configured to trigger a fault and interrupt current flow by opening the multiplexed switch 138. For example, when there is a short-to-ground fault at low-side terminal 136 of the ECM 118, the differential current may reach a value greater than the threshold current 214. In various embodiments, the short-to-ground fault may occur in a wire connecting the fuel injector 112 and the low-side terminal 136 of the ECM 118. In such scenarios, the fourth module 208 triggers the fault and sends a signal to the controller 148 to open the multiplexed switch 138. Thus, the fuel injector 112 is protected from unwanted overcurrent. Further, for fuel injection systems where other fuel injectors share the high-side connection with the faulty fuel injector, the fault detection system 200 results in early detection of the fault thus protecting other connected fuel injectors from failures such as unwanted fueling.

While aspects of the present disclosure have been particularly shown and described with reference to the embodiments above, it will be understood by those skilled in the art that various additional embodiments may be contemplated by the modification of the disclosed machines, systems, circuits and methods without departing from the spirit and scope of the disclosure. Such embodiments should be understood to fall within the scope of the present disclosure as determined based upon the claims and any equivalents thereof.

What is claimed is:

1. A driver circuit configured to operate a fuel injector connected to an Engine Control Module (ECM), the driver circuit comprising:
a power source;
a first switch located on a low-side terminal of the ECM, the first switch being configured to connect and disconnect the fuel injector to and from the power source;
a second switch located on a high-side terminal of the ECM, the second switch being configured to connect and disconnect the fuel injector to and from the power source; and
a fault detection system configured to detect a short-to-ground fault, the fault detection system comprising:
a first module configured to measure a forward current flowing through the high-side terminal of the ECM;
a second module configured to measure a return current flowing through the low-side terminal of the ECM;
a third module configured to compute a differential current based on the forward current and the return current; and
a fourth module configured to compare the differential current with a threshold current, and trigger a fault when the differential current is greater than the threshold current.

2. The driver circuit of claim 1, wherein the fault detection system is further configured to interrupt the flow of the forward current by opening the second switch upon detecting the fault.

3. The driver circuit of claim 1, wherein the fault detection system is further configured to determine a rise time of the differential current and indicate whether the fault is at the high-side terminal or the low-side terminal of the ECM based on the rise time.
